(19) United States
(12) Patent Application Publication
(10) Pub. No.: US 2012/0313126 A1
(43) Pub. Date: Dec. 13, 2012

(54) LED PACKAGE

(75) Inventor: YAU-TZU JANG, Hukou (TW)

(73) Assignee: ADVANCED OPTOELECTRONIC TECHNOLOGY, INC., Hsinchu Hsien (TW)

(21) Appl. No.: 13/366,372

(22) Filed: Feb. 6, 2012

(30) Foreign Application Priority Data
Jun. 8, 2011 (CN) 201110151958.7

(51) Int. Cl. H01L 33/50

(52) U.S. Cl. 257/98; 257/E33.061

(57) ABSTRACT

An LED package comprises an encapsulation layer, an LED die and two electrodes. The LED die is capable of emitting a first light beam with a first wavelength, and, respectively, electrically connecting to the two electrodes. The encapsulation layer covers the LED die, and comprises a luminescent conversion element and a light-compensating element. A heat exhaustion of the luminescent conversion element is converse to that of the light-compensating element. The second and third wave lengths of the second and third light beams generated by the luminescent conversion element and the light-compensating element have oppositely different rates of change when temperatures of the luminescent conversion element and the light-compensating element are increased

### TECHNICAL FIELD

The disclosure relates generally to light emitting diode (LED) packages, and more particularly to an LED package having a stable color expression.

### DESCRIPTION OF THE RELATED ART

Light emitting diodes (LEDs) have low power consumption, high efficiency, quick reaction time, long life and the absence of toxic elements such as mercury being used in their manufacturing. For obtaining a desired color from the LED package, luminescent conversion elements may be evenly disposed inside an encapsulation layer covering an LED die. The luminescent conversion elements are able to absorb a portion of initial light emitted from the LED die, and then transform the initial light into excited light with different wavelength. Thereafter, the other initial light and the excited light are mixed to generate emitting light with multiple wavelengths out of the LED package. During operating, an operating current is directed into the LED die to produce the initial light; however, heat is also generated from the LED die at the same time. The wavelength of the excited light generated by the luminescent conversion elements is changed following the rise of the temperature of the luminescent conversion elements whereby the color of the emitting light of the LED package is changed accordingly. The desired color cannot be maintained. Hence, a new LED device with a stable color expression is required.

### BRIEF DESCRIPTION OF THE DRAWINGS

FIG. 1 is a cross section of an LED package in accordance with a first embodiment of the disclosure.

FIG. 2 is a cross section of an LED package in accordance with a second embodiment of the disclosure.

### DETAILED DESCRIPTION

Exemplary embodiments of the disclosure will be described with reference to the accompanying drawings.

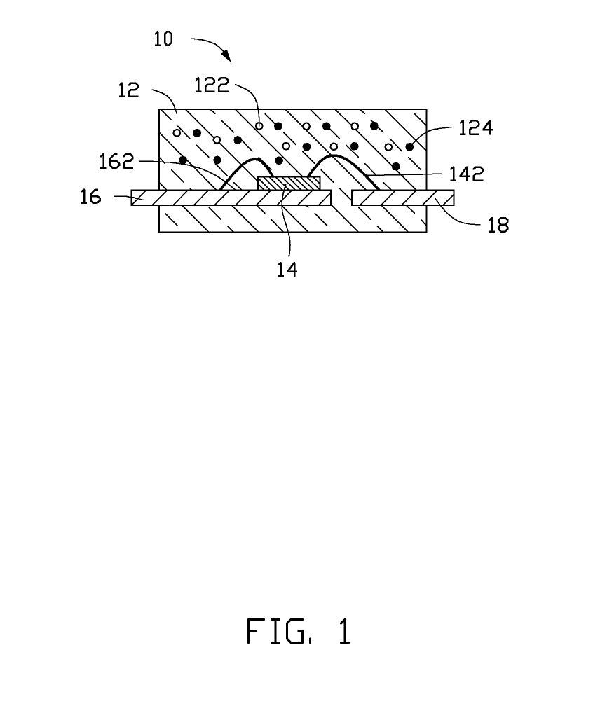

Referring to FIG. 1, the disclosure provides a first embodiment of an LED package 10, which comprises an encapsulation layer 12, an LED die 14 and two electrodes 16, 18.

The two electrodes 16, 18 include a separately formed cathode and an anode. In this embodiment, the two electrodes 16, 18 are made of flat plates, wherein the LED die 14 is disposed on a top 162 of the electrode 16 and, respectively, electrically connects to the two electrodes 16, 18 by conductive wires 142. Alternatively, the supply of electrical power can also be implemented by flip chip or eutectic bonding (not shown). During operating, an operating current is directed into the LED die 14 to produce a first light beam with a first wavelength. At the same time, heat is also generated from the LED die 14.

The encapsulation layer 12 covers the LED die 14 and tops 162 of the two electrodes 16, 18. The encapsulation layer 12 is transparent and can be made of epoxy, silicone or polymers. In this embodiment, the encapsulation layer 12 comprises at least one luminescent conversion element 122 and at least one light-compensating element 124 evenly distributed within the encapsulation layer 12. The at least one luminescent conversion element 122 is capable of shifting the first light beam into a second light beam with a second wavelength. The at least one light-compensating element 124 is capable of shifting the first light beam into a third light beam with a third wavelength. Furthermore, the first light beam, the second light beam and the third light beam are combined to produce mixed light such as white light.

In the disclosure, a heat-exhaustion property of the at least one luminescent conversion element 122 is converse to that of the least one light-compensating element 124. In one embodiment, the heat-exhaustion property of the at least one luminescent conversion element 122 is that the second wavelength of the second light beam transformed from the at least one luminescent conversion element 122 has a raised property as the temperature thereof increases. Oppositely, the heat-exhaustion property of the at least one light-compensating element 124 is that the third wavelength of the third light beam transformed from the at least one light-compensating element 124 has a reduced property as the temperature thereof increases. Accordingly, the complementary effect between the heat-exhaustion properties of the at least one luminescent conversion element 122 and the at least one light-compensating element 124 can prevent deviation of color expression of the LED package 10 by heat exhaustion. Alternatively, the at least one luminescent conversion element 122 can be yttrium aluminum garnet (YAG) phosphor, terbium aluminum garnet (TAG) phosphor, silicate, nitride, oxy-hydrogen, sulfides or any hybrid thereof. The at least one light-compensating element 124 can be copper tetrachloride bis (ethyl-ammonium) salt (C₄H₁₈N₄CuCl₄), and chemical formula thereof is [(CH₃-CH₂)·2NH₂]₂·CuCl₄.

In other embodiments, the heat-exhaustion property of the at least one luminescent conversion element 122 is that the second wavelength of the second light beam transformed from the at least one luminescent conversion element 122 has a reduced property as the temperature thereof increases. Oppositely, the heat-exhaustion property of the at least one light-compensating element 124 is that the third wavelength of the third light beam transformed from the at least one light-compensating element 124 has a raised property as the temperature thereof increases.

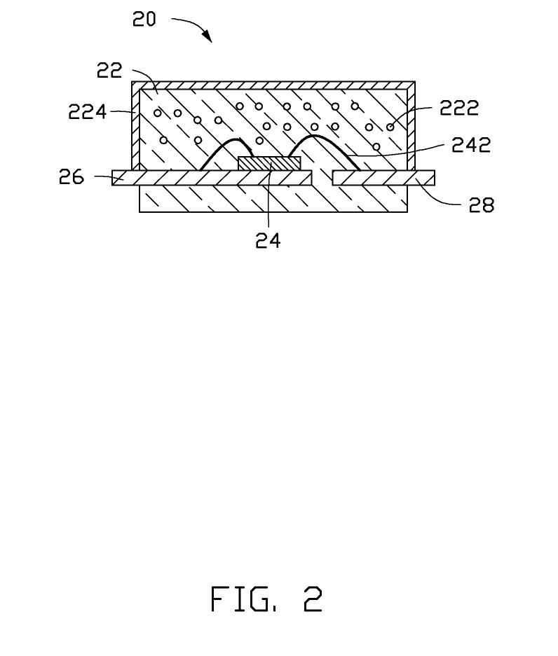

Referring to FIG. 2, the disclosure provides a second embodiment of an LED package 20, which comprises an encapsulation 22, an LED die 24 and two electrodes 26, 28. The two electrodes 26, 28 include a cathode and an anode formed separately. The LED die 24 is disposed on the electrode 26 and electrically connects to the two electrodes 26, 28 via conductive wires 242. The encapsulation layer 22 covers the LED die 24 and top face of the two electrodes 26, 28. In this embodiment, the encapsulation layer 22 comprises at least one luminescent conversion element 222 evenly distributed within the encapsulation layer 22 and at least one light-compensating element 224 covering the encapsulation layer 22.

The second embodiment is similar to the first embodiment, only the difference is that the at least one light-compensating element 224 is disposed on a light emitting surface of the LED package 20. Wavelengths of light beams generated by the at least one light-compensating element 224 and the at least one luminescent conversion element 222 have oppositely different rates of change when temperatures of the elements 224, 222 are increased. In other embodiments, the at least one luminescent conversion element 222 is disposed on a light emitting surface of the LED package 20 and the at least one light-compensating element 224 is evenly distributed within the encapsulation layer 22.

It is to be understood, however, that even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An LED package, comprising:
two electrodes, including a cathode and an anode ;
an LED die, being capable of emitting a first light beam with a first wavelength, and electrically connecting to the two electrodes; and
an encapsulation layer, covering the LED die, comprising at least one luminescent conversion element and at least one light-compensating element, wherein the at least one luminescent conversion element is capable of shifting the first light beam into a second light beam with a second wavelength, the at least one light-compensating element is capable of shifting the first light beam into a third light beam with a third wavelength, a heat-exhaustion property of the at least one luminescent conversion element is converse to that of the least one light-compensating element, the second and third wavelengths of the second and third light beams having oppositely different rates of change when temperatures of the at least one luminescent conversion element and the at least one light-compensating element are increased.

2. The LED package as claimed in claim 1, wherein the at least one luminescent conversion element and the at least one light-compensating element evenly distributed within the encapsulation layer.

3. The LED package as claimed in claim 1, wherein the at least one luminescent conversion element is evenly distributed within the encapsulation layer and the at least one light-compensating element is disposed on a light emitting surface of the LED package.

4. The LED package as claimed in claim 1, wherein the at least one light-compensating element is evenly distributed within the encapsulation layer and the at least one luminescent conversion element is disposed on a light emitting surface of the LED package.

5. The LED package as claimed in claim 1, wherein the encapsulation layer is transparent and made of epoxy, silicone or polymers.

6. The LED package as claimed in claim 1, wherein the at least one luminescent conversion element is made of YAG phosphor, TAG phosphor, silicate, nitride, oxy-hydrogen, sulfides or any hybrid thereof.

7. The LED package as claimed in claim 1, wherein the at least one light-compensating element is copper tetrachloride bis(ethyl-ammonium) salt (C₄H₁₈N₄CuCl₄), and chemical formula thereof is [(CH₃—CH₂)·2NH₂]₂·CuCl₄ .

8. The LED package as claimed in claim 1, wherein the heat exhaustion of the at least one luminescent conversion element is that the second wavelength of the second light beam emitted from the at least one luminescent conversion element has a raised property as the temperature thereof increases.

9. The LED package as claimed in claim 8, wherein the heat exhaustion of the at least one light-compensating element is that the third wavelength of the third light beam emitted from the at least one light-compensating element has a reduced property as the temperature thereof increased.

10. The LED package as claimed in claim 1, wherein the heat exhaustion of the at least one luminescent conversion element is that the second wavelength of the second light beam emitted from the at least one luminescent conversion element has a reduced property as the temperature thereof increases.

11. The LED package as claimed in claim 10, wherein the heat exhaustion of the at least one light-compensating element is that the third wavelength of the third light beam emitted from the at least one light-compensating element has a raised property as the temperature thereof increases.

12. The LED package as claimed in claim 1, wherein the first light beam, the second light beam and the third light beam are combined to produce white light.

13. An LED package, comprising:
two electrodes, including a cathode and an anode ;
an LED die, being capable of emitting a first light beam with a first wavelength, and electrically connecting to the two electrodes;
an encapsulation layer, covering the LED die, comprising at least one luminescent conversion element capable of shifting the first light beam into a second light beam with a second wavelength; and
at least one light-compensating element, covering the encapsulation layer, wherein the at least one light-compensating element is capable of shifting the first light beam into a third light beam with a third wavelength;
wherein a heat exhaustion of the at least one luminescent conversion element is converse to that of the least one light-compensating element, the second and third wavelengths of the second and third light beams having oppositely different rates of change when temperatures of the at least one luminescent conversion element and the at least one light-compensating element are increased.

14. The LED package as claimed in claim 13, wherein the first light beam, the second light beam and the third light beam are combined to produce white light.

15. The LED package as claimed in claim 13, wherein the at least one luminescent conversion element is evenly distributed within the encapsulation layer and the at least one light-compensating element is disposed on a light emitting surface of the LED package.

16. The LED package as claimed in claim 13, wherein the at least one luminescent conversion element is made of YAG phosphor, TAG phosphor, silicate, nitride, oxy-hydrogen, sulfides or any hybrid thereof.

17. The LED package as claimed in claim 16, wherein the at least one light-compensating element is copper tetrachloride bis(ethyl-ammonium) salt (C₄H₁₈N₄CuCl₄), and chemical formula thereof is [(CH₃—CH₂)·2NH₂]₂·CuCl₄.

18. The LED package as claimed in claim 13, wherein the heat exhaustion of the at least one luminescent conversion element is that the second wavelength of the second light beam emitted from the at least one luminescent conversion element has a raised property as the temperature thereof increases, and the heat exhaustion of the at least one light-compensating element is that the third wavelength of the third light beam emitted from the at least one light-compensating element has a reduced property as the temperature thereof increases.

19. The LED package as claimed in claim 13, wherein the heat exhaustion of the at least one luminescent conversion element is that the second wavelength of the second light beam emitted from the at least one luminescent conversion element has a reduced property as the temperature thereof increases, and the heat exhaustion of the at least one light-compensating element is that the third wavelength of the third light beam emitted from the at least one light-compensating element has a raised property as the temperature thereof increases.

20. An LED package, comprising:
two electrodes, including a cathode and an anode;
an LED die, being capable of emitting a first light beam with a first wavelength, and electrically connecting to the two electrodes;
an encapsulation layer, covering the LED die, comprising at least one light-compensating element capable of shifting the first light beam into a second light beam with a second wavelength; and
at least one luminescent conversion element, covering the encapsulation layer, wherein the at least one luminescent conversion element, is capable of shifting the first light beam into a third light beam with a third wavelength;
wherein a heat exhaustion of the at least one luminescent conversion element is converse to that of the least one light-compensating element, the second and third wavelengths of the second and third light beams having oppositely different rates of change when temperatures of the at least one luminescent conversion element and the at least one light-compensating element are increased; and
wherein the first light beam, the second light beam and the third light beam are combined to produce mixed light with multiple wavelengths.
